(19) United States
(12) Patent Application Publication
(10) Pub. No.: US 2005/0287720 A1
(43) Pub. Date: Dec. 29, 2005

(54) Method of fabricating thin film transistor by reverse process

(76) Inventor: Woon Suh Paik, Gyeonggi-do (KR)

Correspondence Address: ROSENBERG, KLEIN & LEE, 3458 ELLICOTT CENTER DRIVE-SUITE 101, ELLICOTT CITY, MD, 21043, US

(21) Appl. No.: 11/157,873

(22) Filed: Jun. 22, 2005

(30) Foreign Application Priority Data
Jun. 29, 2004 (KR) 10-2004-0049345

(51) Int. Cl. H01L 21/00

(52) U.S. Cl. 438/149; 438/157

(57) ABSTRACT

A method of fabricating a thin film transistor is provided. The thin film transistor fabrication method includes the steps of: forming an amorphous silicon film on an insulation substrate; continuously forming a gate oxide film and a gate electrode metal film on the silicon film of the substrate; sequentially patterning the gate electrode metal film and the gate oxide film to thereby form a gate electrode and a gate insulation film; and patterning the amorphous silicon film to thereby form a semiconductor layer which is used as an active region. When a silicon thin film transistor is fabricated according to the above-described steps, foreign matters which are fatal to performance of the thin film transistor can be contained at minimum in an interface between the silicon and the gate oxide film.

### BACKGROUND OF THE INVENTION

1. Field of the Invention

The present invention relates to a method of fabricating a thin film transistor, and more particularly, to a new method of fabricating a thin film transistor in which foreign matters which are fatal to performance of the thin film transistor can be contained at minimum in an interface between the silicon and a gate oxide film, when a silicon thin film transistor is fabricated.

2. Description of the Related Art

According to conventional art, a silicon thin film is formed on a substrate, and a silicon region is patterned by a photographical etching process, to thereby form an active region. Then, a gate oxide film and a gate metal film are sequentially formed thereon to thereby fabricate a thin film transistor.

Hereinbelow, a conventional method of fabricating a thin film transistor will follow with reference to FIGS. 1A through 1D.

FIGS. 1A through 1D are cross-sectional views for explaining a conventional thin film transistor fabrication method.

Referring to FIG. 1A, a buffer layer made of an oxide film is formed on a glass substrate to thereby form an insulation substrate 10, and then an amorphous silicon film is formed on the insulation substrate 10. The amorphous silicon film is patterned using an active region forming mask (not shown), to thereby form a semiconductor layer 11 which is used as an active region.

Referring to FIG. 1B, a photosensitive film which is used for patterning is removed from the substrate, to then sequentially deposit a gate oxide film 13 and a gate electrode metal film 14. Thereafter, using a gate forming mask (not shown), a photosensitive film 12 is formed on the gate electrode metal film 14.

Referring to FIG. 1C, the photosensitive film 12 is used as an etching mask, and the gate electrode metal film 14 and the gate oxide film 13 are patterned in turn, to thereby form a gate electrode 14a and a gate insulation film 13a. Then, the photosensitive film 12 is removed.

Referring to FIG. 1D, high-concentration impurities are ion-injected into the exposed semiconductor layer 11 using the gate electrode 14a as a mask, to thereby define a source region 11S and a drain region 11D which are high-concentration impurities regions. Here, a portion in which impurities are not doped in the semiconductor layer 11 below the gate electrode 14a is set as a channel region 11C of the thin film transistor.

In the case that a thin film transistor is fabricated according to the conventional thin film transistor fabrication method, it is difficult to avoid the following pollutions in an interface between the silicon thin film and the gate oxide film, or in an interface between the gate oxide film and the gate electrode.

First, since a photographic etching process should be undergone using a photosensitive film in order to pattern an active region after an amorphous silicon thin film has been formed, the surface of the amorphous silicon thin film is exposed to various types of chemical materials.

Second, after the gate oxide film has been formed, the gate oxide film can be polluted due to exposure to the air.

However it may be a very small amount of pollution, the pollution may make severe influences upon the electrical features such as a leakage current, a threshold voltage, and an electron mobility of the thin film transistor. Thus, a complicated cleaning process should be executed in order to minimize the pollution. Even though a complicated cleaning process is executed, it may not prevent pollution fundamentally.

### SUMMARY OF THE INVENTION

To solve the above problems, it is an object of the present invention to provide a method of fabricating a thin film transistor which can minimize a pollution material in an interface between a silicon thin film and a gate oxide film, and between gate electrodes without using an additional cleaning process.

To accomplish the above object of the present invention, according to an aspect of the present invention, there is provided a method of fabricating a thin film transistor comprising the steps of: forming an amorphous silicon film on an insulation substrate; continuously forming a gate oxide film and a gate electrode metal film on the silicon film of the substrate; sequentially patterning the gate electrode metal film and the gate oxide film to thereby form a gate electrode and a gate insulation film; and patterning the amorphous silicon film to thereby form a semiconductor layer which is used as an active region.

### BRIEF DESCRIPTION OF THE DRAWINGS

The above and other objects and advantages of the present invention will become more apparent by describing the preferred embodiments thereof in detail with reference to the accompanying drawings in which:

FIGS. 1A through 1D are cross-sectional views for explaining a method of fabricating a thin film transistor according to conventional art; and

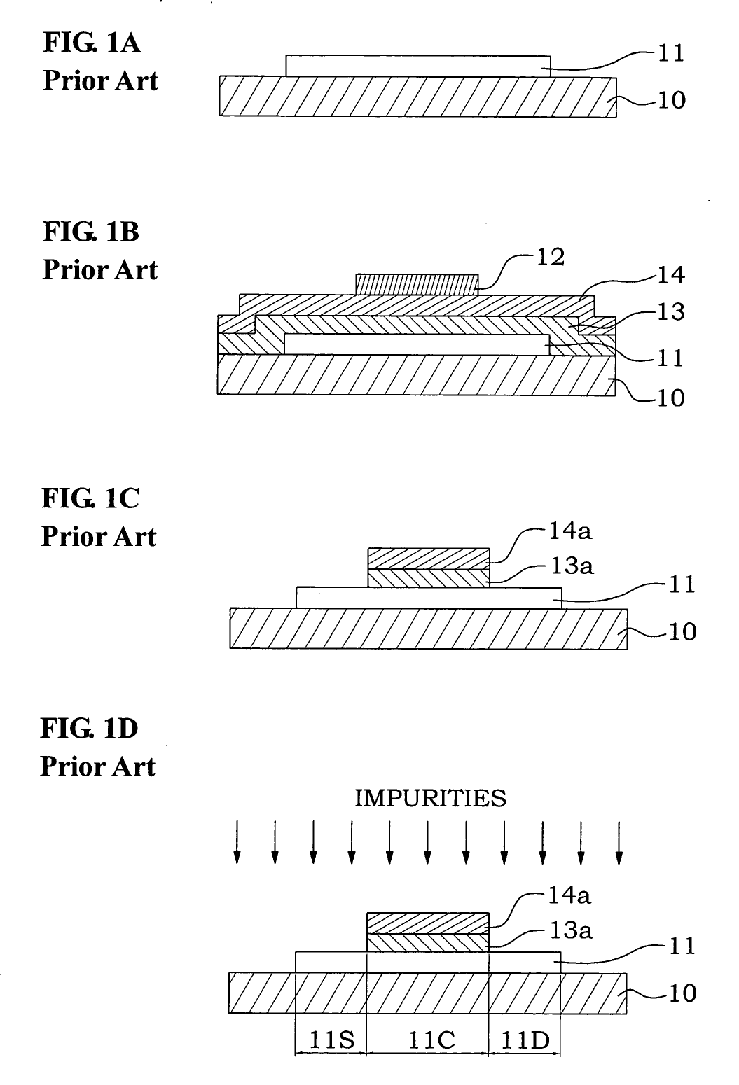

FIGS. 2A through 2D are cross-sectional views for explaining a method of fabricating a thin film transistor by a reverse process according to an embodiment of the present invention.

### DETAILED DESCRIPTION OF THE INVENTION

A preferred embodiment of the present invention will be described with reference to the accompanying drawings.

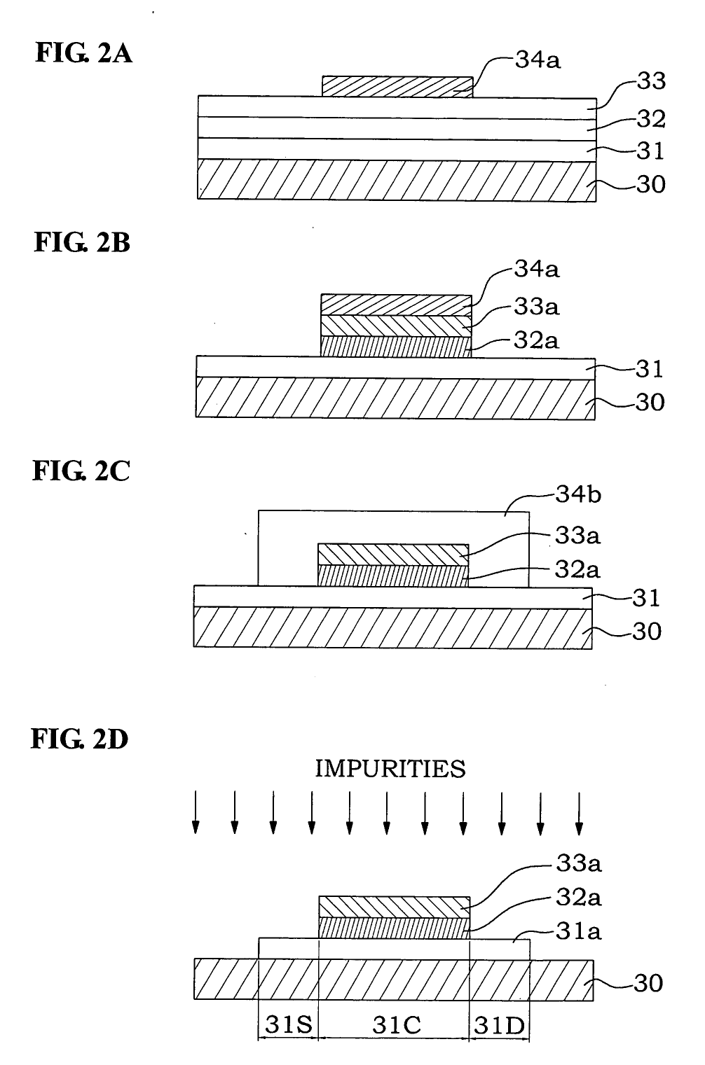

Referring to FIGS. 2A through 2D, a method of fabricating a thin film transistor by a reverse process according to an embodiment of the present invention will be described below.

Referring to FIG. 2A, a buffer layer is formed on a glass substrate to thereby form an insulation substrate 30, and then, an amorphous silicon film 31 is deposited on the insulation substrate 30. Then, a gate oxide film 32 and a gate electrode metal film 33 are continuously formed on the amorphous silicon film 31 without breakage of vacuum.

In this case, the amorphous silicon film 31, the gate oxide film 32, and the gate electrode metal film 33 are continuously deposited, in order to prevent pollution from occurring in the interfaces among the amorphous silicon film 31, the gate oxide film 32, and the gate electrode metal film 33. To do this, equipment connecting a plasma enhanced chemical vapor deposition (PECVD) chamber and a sputtering chamber using a sample charging chamber and a robot arm is used. PECVD is used to continuously deposit the amorphous silicon film 31, and the gate oxide film 32. First, SiH₄ and H₂ are input into the PECVD chamber as a source gas, and then heated up to 550° C. through 600° C. to thereby deposit the amorphous silicon film 31. Thereafter, the source gas is replaced by SiH₄, N₂O, and Ar. Then, the silicon oxide film is deposited at 450° C. through 550° C. Thereafter, using the robot arm, a sample is moved to the sputtering chamber through the sample charging chamber which interconnects two chambers. Here, the sample charging chamber has the same degree of vacuum as that of the sputtering chamber. Then, a gate electrode metal film is formed by sputtering under the atmosphere of the Ar gas.

Thereafter, using a gate forming mask (not shown), a photosensitive film pattern 34a is formed.

Referring to FIG. 2B, using the photosensitive pattern 34a as an etching mask, the gate electrode metal film 33 is patterned to thereby form a gate electrode 33a, and the gate oxide film 32 is patterned to thereby form a gate insulation film 32a.

Referring to FIG. 2C, the photosensitive pattern 34a is removed, and a photosensitive film is deposited on the substrate. Then, using an active region forming mask (not shown), a photosensitive pattern 34b covering the gate electrode 33a, the gate oxide film 32a, and a portion of the amorphous silicon film 31 is again formed.

Referring to FIG. 2D, using the photosensitive pattern 34a as an etching mask, the silicon film 31 is patterned, to thereby form a semiconductor layer 31a, and then remove the photosensitive pattern 34b.

Then, using the gate electrode 33a as a mask, high-concentration impurities are ion-injected onto the substrate, to thereby form a source region 31S and a drain region 31D on the semiconductor layer 31a. Here, a portion in which impurities are not doped in the semiconductor layer 31a below the gate insulation film 32a functions as a channel region 31C of the thin film transistor.

Then, the substrate is heat-treated to crystallize the amorphous silicon film of the semiconductor layer 31a to then be transformed into a poly-crystalline silicon film.

In the embodiment of the thin film transistor fabrication method, the semiconductor layer 31a, the gate insulation film 32a, the gate electrode 33a, and the injected impurities can be made by executing well-known materials under the well-known processing methods and conditions. Thus, the thin film transistor fabrication method according to the present invention is not limited to any particular processing conditions or methods.

As described above, the present invention continuously forms an amorphous silicon thin film, a gate oxide film, and a gate electrode metal film without breakage of vacuum, and then patterns the gate electrode metal film, the gate oxide film, and the silicon thin film, in sequence. Thus, when the silicon thin film is patterned in order to form a semiconductor layer, pollution in each interface can be fundamentally prevented, to thereby enhance the features of a thin film transistor device. Also, the present invention can simplify a total process of fabricating a thin film transistor since it is not necessary to have a complicated cleaning process which should be executed after having a photographical etching process.

As described above, the preferable embodiment of the present invention has been described with reference to the accompanying drawings. However, the present invention is not limited to the above-described embodiment. It is apparent to one who has an ordinary skill in the art that there may be many modifications and variations within the same technical spirit of the invention.

1. A method of fabricating a thin film transistor comprising the steps of:
forming an amorphous silicon film on an insulation substrate;
continuously forming a gate oxide film and a gate electrode metal film on the silicon film of the substrate;
sequentially patterning the gate electrode metal film and the gate oxide film to thereby form a gate electrode and a gate insulation film; and
patterning the amorphous silicon film to thereby form a semiconductor layer which is used as an active region.

2. The thin film transistor fabrication method of claim 1, further comprising the steps of:
ion-injecting high-concentration impurities into the semiconductor layer on the substrate, to thereby define a source region and a drain region; and
crystallizing the amorphous silicon film on the semiconductor layer by executing a heat treatment with respect to the substrate, to then be transformed into a poly-crystalline silicon film.

3. The thin film transistor fabrication method of claim 1, wherein the step of continuously forming a gate oxide film and a gate electrode metal film is continuously accomplished without a breakage of vacuum after forming the amorphous silicon film.

4. The thin film transistor fabrication method of claim 1, wherein the continuous deposition of the amorphous silicon film, the gate oxide film, and the gate electrode metal film is executed using equipment in which a plasma enhanced chemical vapor deposition (PECVD) chamber and a sputtering chamber through which the gate electrode metal film is sputtered, are mutually connected with each other.
